(19) United States
(12) Patent Application Publication
(10) Pub. No.: US 2010/0133693 A1
(43) Pub. Date: Jun. 3, 2010

(54) Semiconductor Package Leads Having Grooved Contact Areas

(75) Inventor: Mohamad Ashraf Mohd ARSHAD, Kuala Lumpur (MA)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/405,420

(22) Filed: Mar. 17, 2009

Related U.S. Application Data
(60) Provisional application No. 61/119,435, filed on Dec. 3, 2008.

(51) Int. Cl. H01L 23/488; H01L 21/50

(52) U.S. Cl. 257/762; 438/123; 257/E23.023; 257/E21.499; 257/779

(57) ABSTRACT

A packaged semiconductor device (100) has a first (110) and a second (111) side, the second side including a plurality of metal terminals (120) extending to the first side. Each terminal includes an oblong groove (122) extending to the first side and ending in an orifice (123) at the first side. The terminals are made of a base metal and may have a solder-wettable surface except for the terminal surface (121) exposed at the first device side.

### FIELD OF THE INVENTION

The present invention is related in general to the field of semiconductor devices and processes, and more specifically to the structure and fabrication method of Small Outline No-Lead (SON) and Quad Flat No-Lead (QFN) devices having solder contact areas enlarged by grooves.

### DESCRIPTION OF RELATED ART

Semiconductor Small Outline No-Lead (SON) and Quad Flat No-Lead (QFN) devices are typically fabricated by assembling a plurality of chips on a strip of metallic leadframe. The leadframe is laid out to include for each device the needed chip pads and coordinated lead segments. In order to miniaturize the devices and conserve area in the layout of the leadframe strip, the layout is commonly designed so that the segments of one device are connected directly to the respective segments of the adjacent devices.

The majority of leadframes is made of a base metal such as copper or an alloy including copper, and plated with layers of solderable metal, such as a layer of nickel followed by a layer of palladium. After the chips are assembled on the pads and wire bonded to the segments, the leadframe strip is encapsulated in a protective plastic compound while those segment areas intended for soldering are not covered by encapsulation compound. Subsequently, discrete devices are singulated from the strip by cutting through the encapsulation compound and the plated metal segments with a saw. As a consequence of the sawing step, the segments have a side surface where the base metal has been exposed by the saw. Finally, the discrete devices are assembled on a substrate by solder-connecting the not-covered segment areas to metallic pads of the substrate.

### SUMMARY OF THE INVENTION

Applicant found in the assembly step of the devices that solder is wetting the saw-exposed base metal at the cut line only inconsistently and unreliably. Applicant's analysis of the exposed metal surface revealed erratic oxidation of the base metal and consequently erratic wettability by solder. As a consequence, the solder meniscus expected at a wettable surface cannot reliably form and a top-view visual inspection of the soldered devices has to register the absence of the tell-tale meniscus, which would confirm a reliable solder assembly. Thus, the inspection has to declare a yield loss even if the device is actually an electrically good device.

Applicant solved the problem of creating a clearly visible meniscus by forming one or more grooves, or furrows, into the leadframe segment surface before the leadframe plating step (“grooving” the segment surface). The orifice of the groove at the cut line allows solder to spread from the orifice as a fillet, and to form a meniscus unmistakably visible to top-view inspection. In addition, the enhanced solderable surfaces of the grooves add to the solderable surface of the segments, thus increasing the solder assembly strength.

The preferred leadframe material is an alloy including copper. During the leadframe formation process, at least one groove is etched or stamped into the length of each segment, whereby the grooves are deepened from that leadframe surface, which will become the outside of the finished device. Together with this surface, the grooves are then plated with layers of metals such as nickel and palladium to provide them with affinity for solder wetting. After the chip assembly and encapsulation steps, adjacent devices of the leadframe are singulated by sawing, whereby the segments with the grooves are halved and each groove half obtains an orifice at the cut line. In the device attachment step, enough solder is provided to the plated outside surface of the device so that solder is also wetting and filling the grooves, whereby solder protrudes out of each orifice to form the desired telltale meniscus.

It is a technical advantage of the invention that no process or material change of the device is required, only the tool for stamping or etching the leadframe has to be modified. On the other hand, the impact of the invention on yield saving and reliability of the assembled device is significant.

### BRIEF DESCRIPTION OF THE DRAWINGS

FIG. 1 shows a schematic perspective view of a semiconductor device of the QFN/SON type, illustrating the terminals with the grooves made into the terminals according to the invention.

FIG. 2 depicts a schematic perspective view of a semiconductor device of the QFN/SON type soldered onto a substrate, illustrating the solder protruding from the orifices of the grooves made into the terminals according to the invention.

FIG. 3 illustrates an enlarged side view of the attached semiconductor device of FIG. 2, showing the solder meniscus protruding from the orifice of the groove in the terminal.

FIG. 4A is a schematic bottom view of a strip portion of a plurality of packaged QFN/SON devices, wherein the terminals and the chip pad surfaces intended for solder attachment remain un-encapsulated.

FIG. 4B depicts an enlarged bottom view of the individual terminals highlighted in FIG. 4A, showing the grooves in the terminals according to the invention. The saw street is indicating the location of the cut by the singulation step.

FIG. 5 is a cutaway of the terminals in FIG. 4B along a cut indicated by arrows “5”.

FIG. 6A illustrates schematic cross sections and a schematic front view of a terminal with the groove according to the invention.

FIG. 6B shows a schematic cross section of a groove with the extent of the wettable surface.

FIG. 6C depicts a schematic cross section of a device terminal with a groove soldered to a substrate, including the solder meniscus protruding from the orifice of the groove.

### DETAILED DESCRIPTION OF THE PREFERRED EMBODIMENTS

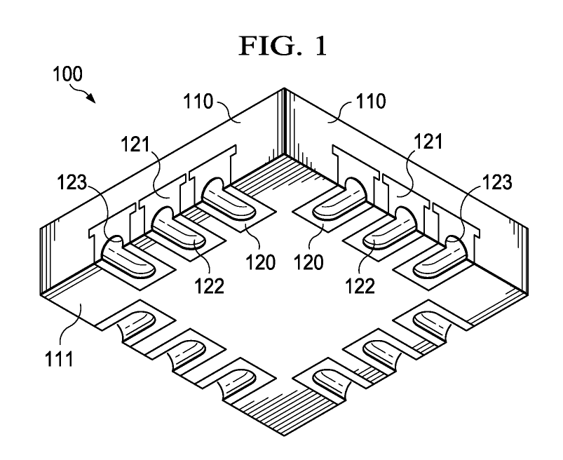

FIG. 1 is a schematic perspective view of the bottom surface of an exemplary semiconductor device, generally designated 100, of the Small Outline No-Lead (SON) or Quad Flat No-Lead (QFN) family. The device is packaged in an insulating encapsulation material, preferably a molding compound, and has metal terminals 120, preferably made of copper or a copper alloy as the base metal. The SON/QFN device family covers a wide spectrum of device shapes (usually hexahedron, square or rectangular cross section), sizes (length less than 1 mm to more than 10 mm), and numbers and distributions of terminals. To mention only a few examples of the terminal numbers, SON/QFN devices sized 4 mm×4 mm may have 16 or 24 terminals; devices sized 5 mm×5 mm may have 16, 20, or 32 terminals; devices sized 6 mm×6 mm may have 20 or 28 terminals; devices sized 7 mm×7 mm may have 32 or 44 terminals; and a device sized 8 mm×8 mm may have 56 terminals. In the latter example, the pitch center-to-center of the terminals is about 0.5 mm, and the width of each terminal about 250 μm.

FIG. 1 displays two of the peripheral surfaces 110 of the device package and the bottom surface 111 of the package. It should be mentioned that herein the peripheral device surfaces 110 are referred to as first sides, and the bottom surface 111 is referred to as the second side. As FIG. 1 shows, the terminals are anchored in the encapsulation material and extend to a first side, where they show the face 121 of the terminal. In the SON/QFN device example of FIG. 1, the terminals are distributed so that they extend to one of the four sides; in other devices, one or more sides may be free of terminals.

As FIG. 1 shows, each terminal 120 includes an oblong groove 122, which have a length extending to the first side 110. At the first side, each groove ends in an orifice 123. The grooves have a width in conformance with the size of the terminal. While FIG. 1 depicts only one groove per terminal, in other devices at least one terminal may have more than one groove.

As mentioned, the terminals are made of a base metal, preferably copper. In order to ensure good solderability of the terminals, it is preferred that the terminals on the second device side 111 have a surface wettable by solder. An example of a wettable surface is a layer of nickel in contact with the copper followed by an outermost layer of gold or palladium in contact with the nickel. The solder-wettable surface on the second side 111 is preferably also in all grooves 122; as an example, the nickel-palladium, nickel-gold surface layer covers also the surface of the grooves.

Due to the fabrication method described below, the base metal of the terminals is exposed at the first device side 110. Consequently, the terminal face 121 at the first device side 110 displays the base metal without the solder-wettable surface.

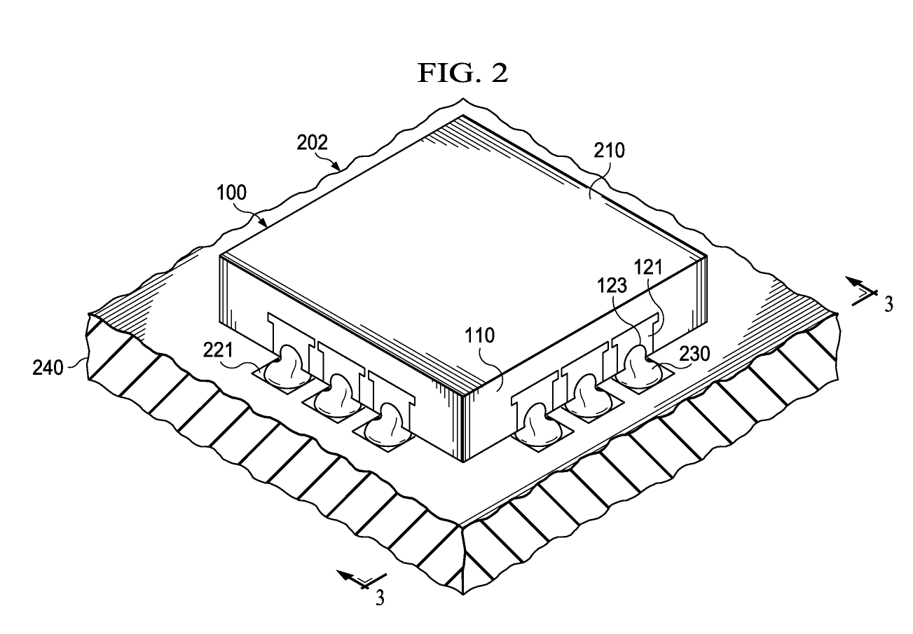

FIG. 2 illustrates the exemplary packaged semiconductor device 100 of the Small Outline No-lead (SON) or Quad Flat No-lead (QFN) family attached to a substrate 202. In the view of FIG. 2, the outline of device 100 shows the top surface 210 and two of the peripheral sides 110. The peripheral sides also include the faces 121 of the metallic device terminals, which are anchored in the encapsulation material. Furthermore, the face 121 of the terminals indicates the groove orifice 123 at the first side 110.

Substrate 202 may be made of an insulating material 240 and includes metallic contact pads 221 (it may also include integral conducting traces not shown in FIG. 2). Pads 221 are positioned in the locations of the terminals and thus can serve as sites for attaching device 100 onto substrate 202. Substrate material 240 may be a polyimide film, or an FR-4-based board, sometimes strengthened by glass fibers, or any other suitable material. Preferred metal for pads 221 is copper or a copper alloy, preferably with a surface wettable by solder such as a layer of nickel in contact with the copper and a layer of gold or palladium in contact with the nickel.

As FIG. 2 shows, the attachment of device 100 onto substrate 202 is accomplished by solder. Specifically, FIG. 2 indicates that the solder fills the grooves, since they have a wettable surface, and is protruding from the orifice 123 onto pad 221, which also has a wettable surface. The protrusion looks like a solder stream approximately shaped as a meniscus between the terminal orifice 123 and the substrate pad 221. These meniscus-shaped protrusions are clearly visible, when the assembled device is viewed from top.

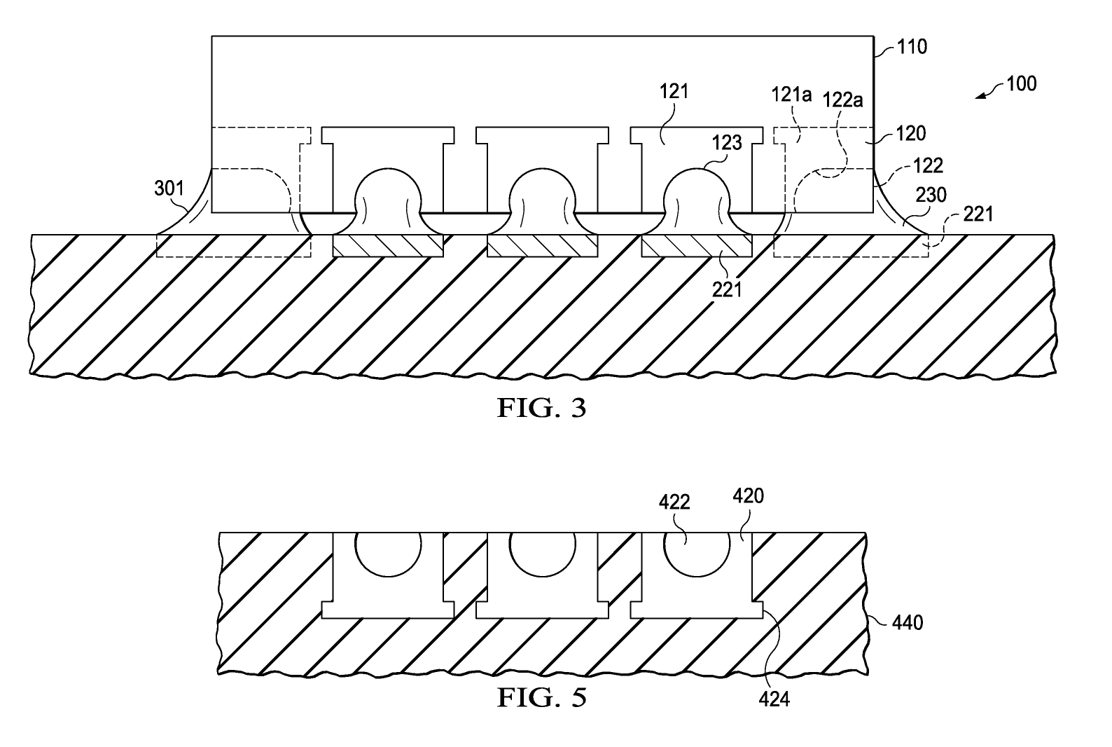

The assembly of device 100 on the substrate 202 and the solder meniscus are illustrated in more detail in FIG. 3, which views one of the first sides 110 of device 100. First side 110 shows the faces 121 of terminals 120. The depth of the terminals is indicated by an X-ray view in dashed outline 121a. The terminals have grooves and the depth of the grooves 122 is also indicated by an X-ray view in dashed outline 122a. The solder 230 is protruding from the terminal orifice up to the height of the groove and is wetting the substrate pad 221; the solder forms a projection in the shape of meniscus 301 between the orifice 123 and the substrate pad 221.

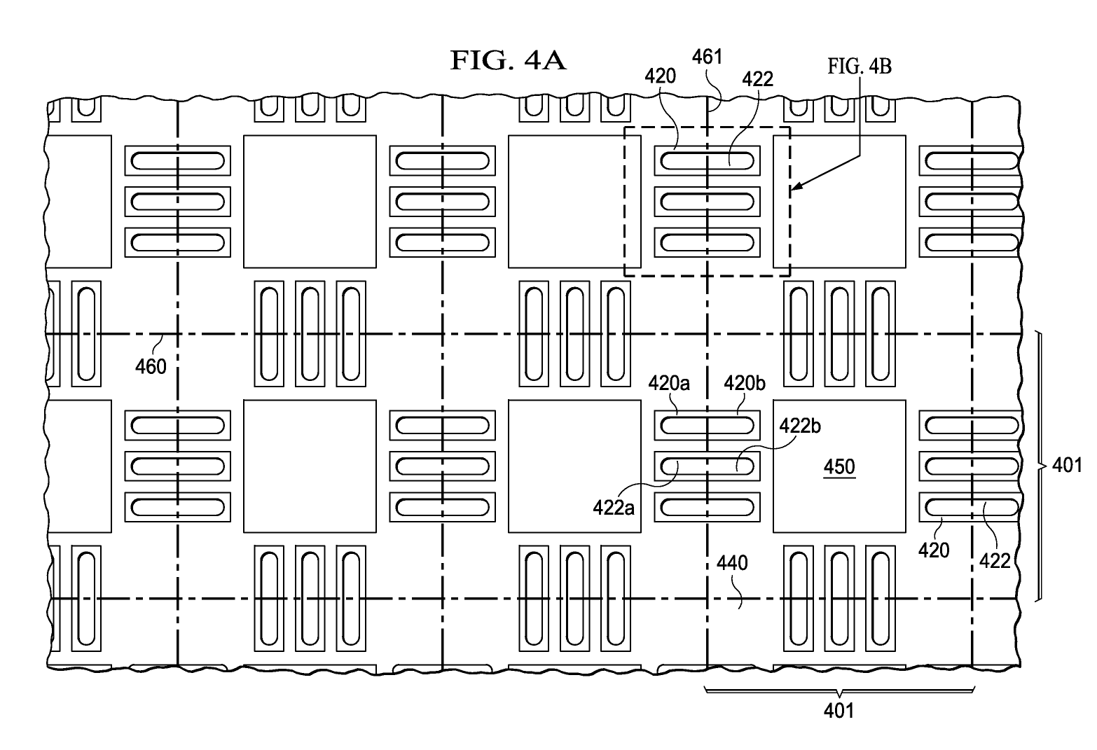

FIG. 4A shows the bottom of a strip portion of encapsulated exemplary SON/QFN devices 401. The encapsulation is an insulator material 440, for instance a molding compound. In FIG. 4A, the terminals 420 of the devices are un-encapsulated to allow electrical contact to and physical connection with external parts. In addition, in this particular example, the chip pads 450 remain free of encapsulation compound so that the thermal path from the attached chip to the eventual heat sink in the substrate is minimized. As FIG. 4A indicates, terminals 420 have an elongated shape with a certain length. The terminals have an oblong groove 422 fabricated into the terminal material from the bottom surface. The groove of each terminal extends approximately over the length of the terminal. In some devices, there may be one or more terminals, which exhibit more than one groove. Preferably, these grooves are parallel to each other.

Further shown in FIG. 4A are dashed parallel lines 460, and dashed parallel lines 461. These lines indicate the cut lines (or saw street) for the saw in the singulation process of the strip. Lines 460 and lines 461 are oriented at right angles to each other. The cut lines are placed so that they sever the elongated terminals 420 together with the elongated grooves 422 into two halves 420a and 420b. Since the two terminal halves originate from the elongated terminal 420, the two terminal halves 420a and 420b are contiguous. In analogous manner, the cut lines 460 and 461 sever the elongated grooves 422 into two halves 422a and 422b. Since the two groove halves originate from the elongated groove 422, the two groove halves 422a and 422b are contiguous.

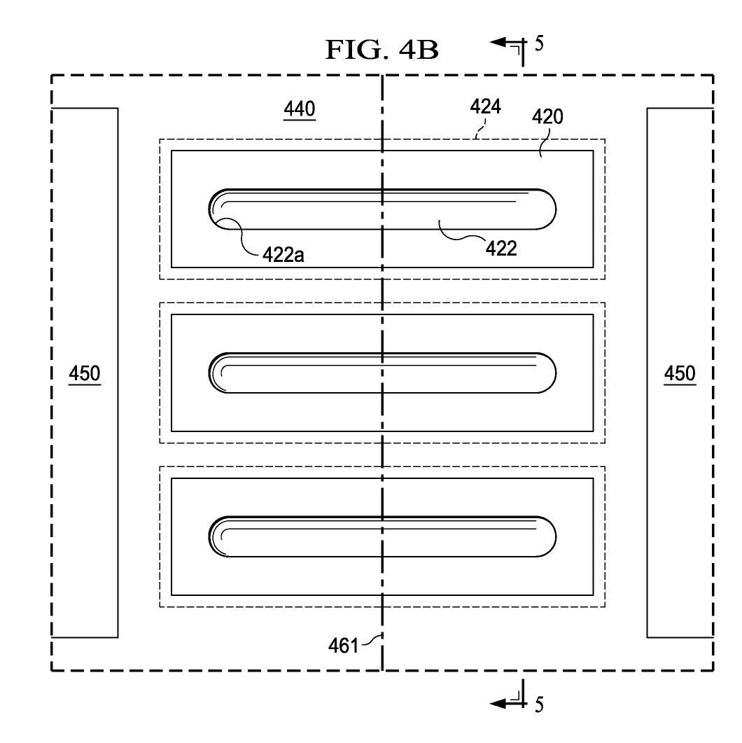

A region of FIG. 4A marked by dashed outlines “FIG. 4B” is enlarged in FIG. 4B. In addition to terminals 420 and grooves 422, FIG. 4B illustrates a metal flange 424 for each terminal 420, which, in this view of the bottom surface, is hidden under the rim of the encapsulation compound 440 (and therefore visible only in X-ray fashion and thus outlined in dashed contour). Flange 424 is needed to provide an anchor for the terminal in the encapsulation compound. Following the cutaway line designated “5” in FIG. 4B, FIG. 5 depicts the metal flange 424 of terminal 424 in cross section. FIG. 5 also depicts a cross section of groove 422.

Referring now to the view of the bottom surface in FIG. 4B, the elongated structure of terminal 420 is echoed by the elongated structure of groove 422. The end portions 422a of oblong groove 422 are shaped by the method of forming the groove (stamping or etching, see below). As examples, the end portions 422a may show a rounded contour, or a contour with corners, a slightly irregular contour, or any other outline.

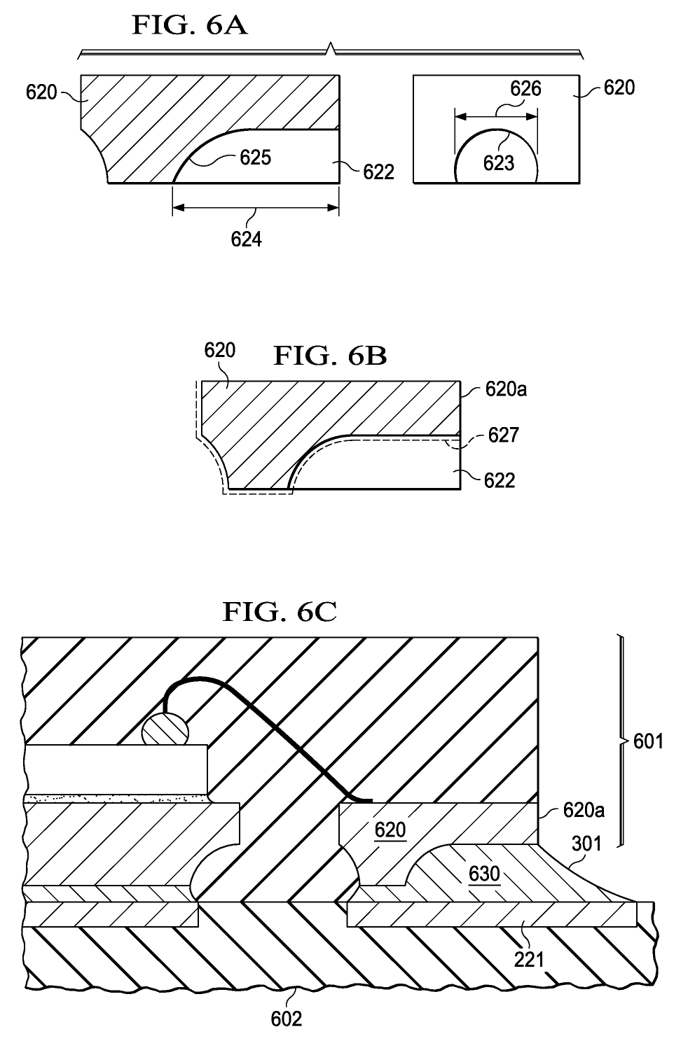

FIG. 6A shows a cross section of a terminal 620 with a groove 622 and the corresponding front view of the terminal 620 with the orifice 623 of the groove. In the fabrication process of the groove, the length 624 of groove 622 can be selected as suitable; also, the curvature 625 can be selected as suitable. In addition, the diameter 626 of the groove and its overall outline can be selected as suitable. Since the base metal of terminal 620 preferably includes copper, it is preferred, as FIG. 6B points out, that the groove has an outer surface 627 with affinity to solder wetting. Examples of such prepared surface 627 include a layer of nickel in contact with the base metal (copper) and an outermost layer of a noble metal, such as palladium and gold, in contact with the nickel. The preparation of surface 627 by depositing the metal layers right after the leadframe patterning (see below). Face 620a of terminal 620 does not have the surface preparation 627 of the groove; face 620a does not include the wettable metal layer, which is preferably deposited in a plating step preceding the encapsulation process (see below). The reason for the exposed base metal at surface 620a is the step of singulating the devices from the strip (see below), which is preferably performed by sawing.

FIG. 6C illustrates the distribution of the solder 630 after attaching the device 601 to a substrate 602. The solder distribution is a consequence of the groove preparation (shown in FIG. 6B). Solder 630 wets the surface of the groove 620 and protrudes from the groove orifice as a meniscus 301 onto substrate pad 221. On the other hand, solder may not wet face 620a of terminal 620, since this surface exposes the base metal of the terminal, which includes copper and thus easily oxidizes, preventing reliable solder wetting.

Another embodiment of the invention is a method for fabricating a metallic leadframe for us in semiconductor devices. In the method, a strip of a base metal sheet, such as copper or a copper alloy, is selected. At this stage of the method, the strip may actually be long and processed in a reel-to-reel technique. The sheet has two surfaces and may have a thickness in the range from 100 to 300 μm; the sheet may be thicker or thinner. The strip is patterned, by a stamping or an etching technique, for the use as a leadframe in semiconductor devices. The patterned leadframe includes a plurality of adjoining structures for assembling semiconductor chips and providing electrical leads of the assembled chips to external parts. Included in the pattern are elongated leads of contiguous device segments; the leads have certain length.

In the next process steps, grooves or furrows are formed into one of the surfaces of the elongated leads. This surface will later become the surface for contact or attachment to external parts. The grooves extend approximately over the length of the elongated leads and are thus also elongated. The grooves may have a depth of about 50 to 75% of the base metal sheet and a cross section, which may be round or angled. The preferred techniques of forming the elongated grooves include a mechanical stamping technique and a chemical etching technique. Alternatively, the grooves may be formed by a laser. The capability of each technique determines the groove width achievable. Each elongated lead should have at least one groove; however, if the lead width permits, more than one groove may be formed parallel to each other.

In the preferred fabrication flow, the next step is a deposition step of solder-wettable metals at least over the surface of the leads with the grooves. The preferred method is a plating technique. Preferably, the deposition step includes first the deposition of a layer of nickel in contact with the base metal (for example copper) and then the deposition of a layer of palladium or gold in contact with the nickel. In an alternative fabrication flow, the deposition of extra metal layers is omitted in favor of using a chemical flux for facilitating the soldering step. The goal of either fabrication flow is to prepare the groove surface so that it enables solder to reliably wet the groove surface and thus to fill the grooves with solder.

Next, a suitable portion of the patterned leadframe strip is selected. As described, the pattern includes elongated leads composed of contiguous device segments, wherein each lead has a length and at least one groove extending over the length, formed into one strip surface. The strip surface with the groove is referred to as the first surface; the opposite surface is referred to as the second strip surface. As described above, the strip may have one or more deposited layers of metals, which are solder-wettable; the layers cover the first surface of the leads including the grooves.

One or more semiconductor chips are assembled on the second surface of the leadframe strip. The assembly may use chip attachment and wire bonding, or flip-chip attachment. After the chip assembly. The leadframe strip is encapsulated in a polymer compound, preferably a molding compound, so that the first surface of the leads together with the grooves remains un-encapsulated. In this manner, the un-encapsulated leads of the leadframe can be accessed for electrical connection and, in the next process step, the lead segments can become the terminals of the encapsulated device.

Next, the strip is subjected to singulation in order to create discrete devices. The preferred singulation technique is sawing, alternatively, a laser may be used. The sawing proceeds along cut planes through the encapsulation compound and the leads. As a consequence, the leads are separated and become the terminals of the discrete devices, each terminals having at least one groove. By the separation process, the base metal of the leads is exposed at the terminals face, which, in the case of copper, is easily oxidized; in addition, the orifice of the grooves is visible at the terminal face.

When a singulated device is being solder-attached to a substrate, a solder connection is formed between the device terminals and the contact pads of the substrate. The solder is wetting the plated first surface of the terminals and the grooves. By having the wettable grooves, the solder can find a considerably enlarged area for the attachment grip and for solder volume than it can in devices with a flat terminal contact area not exceeding the footprint. The result is a significantly enhanced reliability of the attachment. Furthermore, as stated above, the solder is protruding from the orifice of the groove, forming a fillet with a meniscus surface along the substrate pad. The meniscus can be optically detected by process inspection, enhancing the quality assurance of the assembly step.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to any type of semiconductor chip, discrete or integrated circuit, and the material of the semiconductor chip may include silicon, silicon germanium, gallium arsenide, or any other semiconductor or compound material used in integrated circuit manufacturing.

As another example, the invention can be applied beyond the assembly of semiconductor devices to the solder attachment of any body with metal terminals, which can be enhanced by forming oblong grooves in the terminal. The grooves enlarge the contact area for the solder beyond the terminal footprint, and provide clear visibility of the solder fillet as a protrusion, possibly shaped as a meniscus; the visual inspection of the solder fillet thus enhances quality control.

It is therefore intended that the appended claims encompass any such modifications or embodiments.

I claim:

1. An apparatus comprising:
a packaged semiconductor device having a first and a second side, the second side including a plurality of terminals extending to the first side; and
each terminal including a groove also extending to the first side and ending in an orifice at the first side.

2. The apparatus of claim 1 wherein the terminals are having a base metal and a solder-wettable surface, the base metal without the solder-wettable surface exposed at the first device side.

3. The apparatus of claim 2 further including the solder-wettable surface in the grooves.

4. The apparatus of claim 3 wherein the base metal includes copper and the wettable metallurgical surface includes a layer of nickel in contact with the copper and a layer of palladium or gold in contact with the nickel.

5. The apparatus of claim 4 further including a substrate, unto which the device terminals are attached by solder, wherein the solder is filling the grooves and protruding from the orifices in a meniscus between the orifice and the substrate.

6. A method for fabricating a leadframe for use in semiconductor devices, comprising the steps of:
selecting a strip of a base metal patterned for use as a leadframe of adjoining semiconductor devices, the pattern including elongated leads of contiguous device segments, the leads having a length; and
forming grooves into one surface of the leads, the grooves extending over the length of the leads.

7. The method of claim 6 wherein the base metal includes copper.

8. The method of claim 7 further including the step of plating a layer of a solder-wettable metal over the surface of the leads including the grooves.

9. The method of claim 8 wherein the solder-wettable metal includes a layer of nickel in contact with the copper and a layer of palladium or gold in contact with the nickel.

10. The method of claim 6 wherein the step of forming includes a mechanical stamping technique.

11. The method of claim 6 wherein the step of forming includes a chemical etching technique.

12. A method for fabricating a semiconductor device comprising the steps of:
providing a patterned leadframe strip of a base metal, the strip having a first and a second surface, the pattern including elongated leads composed of contiguous device segments, each lead having a length and one groove extending over the length, formed into the first surface;
assembling semiconductor chips on the second surface of the leadframe strip;
encapsulating the leadframe strip in a polymer compound so that the first surface of the leads remains un-encapsulated; and
singulating discrete devices from the strip by sawing along cut planes through the compound and the leads, wherein the leads are separated in the device terminals and the base metal of the leads and an orifice for the grooves in each terminal are exposed.

13. The method of claim 12 further including, after the step of providing, the step of depositing a layer of solder-wettable metal on the first surface of the leads including the grooves.
